(19) United States
(12) Patent Application Publication
(10) Pub. No.: US 2026/0068463 A1
(43) Pub. Date: Mar. 5, 2026

(54) DISPLAY PANEL AND DISPLAY APPARATUS

(71) Applicants: Mianyang HKC Optoelectronics Technology Co.,Ltd., MIANYANG (CN); HKC CORPORATION LIMITED, SHENZHEN (CN)

(72) Inventors: Qin LIANG, MIANYANG (CN); Yangling TANG, MIANYANG (CN); Zhisheng XIE, SHENZHEN (CN); Xiufeng ZHOU, MIANYANG (CN); Lidan YE, MIANYANG (CN)

(73) Assignees: Mianyang HKC Optoelectronics Technology Co.,Ltd., MIANYANG (CN); HKC CORPORATION LIMITED, SHENZHEN (CN)

(21) Appl. No.: 19/301,941

(22) Filed: Aug. 16, 2025

(30) Foreign Application Priority Data
Aug. 30, 2024 (CN) 202411215622.6

(51) Int. Cl. H10K 59/131; H10K 59/122; H10K 77/10; H10K 102/00

(52) U.S. Cl. CPC H10K 59/131; H10K 59/122; H10K 77/111; H10K 2102/311

(57) ABSTRACT

The present application provides a display panel and a display apparatus. The display panel includes a flexible substrate, a plurality of pixel definition layers, a plurality of sub-pixels, a plurality of isolation structures, and a plurality of connecting wires. The isolation structures surround the sub-pixels to isolate adjacent sub-pixels, so that adjacent sub-pixels may be independently encapsulated. Two adjacent isolation structures are connected by a corresponding one of the connecting wires. The connecting wire and the isolation structure are connected to each other through a reinforcement portion. Along a direction from a pixel opening to an extension region, a width of the reinforcement portion is greater than a width of an isolation portion. Along a width direction of the isolation structure, a width of the connecting wire is smaller than a width of the reinforcement portion.

### CROSS REFERENCE TO RELATED APPLICATIONS

The present disclosure claims priority to Chinese Patent Application No. 202411215622.6, entitled “DISPLAY PANEL AND DISPLAY APPARATUS”, filed Aug. 30, 2024, the entire contents of which are incorporated herein by reference.

### TECHNICAL FIELD

The present disclosure relates to the technical field of display screens, and in particular to a display panel and a display apparatus.

### BACKGROUND

Stretchable display technology enables a display screen to be stretchable and to be stretched in all directions to change its shape for adapting to surfaces of any shape. A stretchable screen may be flexibly applied in various fields, such as consumer electronics, public displays, medical, biological, wearable devices, gaming, fashion, and automotive scenarios. When the display screen is stretched, the tensile strength between a connecting wire and an isolation structure may directly affects the quality and life of the display screen. Therefore, how to enhance the tensile strength of the connecting wire and the isolation structure is a technical problem that needs to be solved urgently.

### SUMMARY OF THE DISCLOSURE

The present disclosure provides a display panel, including: a flexible substrate, defined with a plurality of pixel regions and a plurality of extension regions; a plurality of pixel definition layers, arranged within the pixel regions respectively to form a plurality of pixel openings; a plurality of sub-pixels, arranged in the pixel openings respectively, each of the sub-pixels including an anode, an organic light-emitting layer, and a cathode, which are sequentially stacked along a direction from close to the flexible substrate to away from the flexible substrate; a plurality of isolation structures, arranged on the pixel definition layers respectively and surrounding the sub-pixels, a portion of each of the isolation structures extending toward a side away from a corresponding one of the pixel openings to form a reinforcement portion, another portion of each of the isolation structures connecting the reinforcement portion being an isolation portion; and along a direction from the corresponding one of the pixel openings to a corresponding one of the extension regions, a width of the reinforcement portion being greater than a width of the isolation portion; a plurality of connecting wires, arranged in the extension regions respectively, each of the connecting wires being connected between two adjacent isolation structures through reinforcement portions of the two adjacent isolation structures; and along a width direction of each of the isolation structures, a width of a corresponding one of the connecting wires being smaller than a width of the reinforcement portion.

The present disclosure further provides a display apparatus, including the display panel according to the embodiment mentioned above and a power supply. The power supply is electrically connected to the display panel for supplying power to the display panel.

Other features and advantages of the present disclosure will become apparent from the following detailed description, or may be learned in part by the practice of the present disclosure.

It should be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrating the embodiments conforming to the present disclosure, and are used together with the specification to explain the principles of the present disclosure. Obviously, the drawings in the following description are only some embodiments of the present disclosure. For those skilled in the art, other drawings may also be obtained according to these drawings without any creative efforts.

FIG. 1 is a schematic plan view of a display panel according to some embodiments of the present disclosure.

FIG. 2 is an enlarged schematic view of region A shown in FIG. 1.

FIG. 3 is a schematic cross-sectional view along line I-I shown in FIG. 2.

FIG. 4 is a schematic structural view of a first embodiment of an isolation structure according the present disclosure.

FIG. 5 is a schematic cross-sectional view along line II-II shown in FIG. 2.

FIG. 6 is a schematic structural view of a second embodiment of an isolation structure according the present disclosure.

FIG. 7 is a schematic structural view of a third embodiment of an isolation structure according the present disclosure.

FIG. 8 is a schematic structural view of a fourth embodiment of an isolation structure according the present disclosure.

FIG. 9 is a schematic structural view of a fifth embodiment of an isolation structure according the present disclosure.

FIG. 10 is a schematic structural view of a first embodiment of a connecting wire according the present disclosure.

FIG. 11 is a schematic structural view of a second embodiment of a connecting wire according the present disclosure.

FIG. 12 is a schematic structural view of a third embodiment of a connecting wire according the present disclosure.

FIG. 13 is a schematic structural view of a display panel after encapsulation according to some embodiments of the present disclosure.

FIG. 14 is a schematic structural view of a display apparatus according to some embodiments of the present disclosure.

### DETAILED DESCRIPTION

Exemplary embodiments will now be described more comprehensively with reference to the accompanying drawings. However, the exemplary embodiments may be implemented in a variety of forms and should not be construed as being limited to the examples set forth herein. Rather, these embodiments are provided so that the present disclosure will be more thorough and complete, and concept of the exemplary embodiments will be fully conveyed to those skilled in the art.

In addition, described features, structures, or characteristics may be combined in any suitable manner in one or more embodiments. In the following description, many specific details are provided to give a thorough understanding of the embodiments of the present disclosure. However, those skilled in the art will recognize that the technical solutions of the present disclosure may be practiced without one or more of the specific details, or other methods, components, devices, steps, etc. may be adopted. In other cases, well-known methods, devices, implementations, or operations are not shown or described in detail to avoid obscuring various aspects of the present disclosure.

The present disclosure is further described in detail below in conjunction with the accompanying drawings and specific embodiments. It should be noted that the technical features involved in each embodiment of the present disclosure described below may be combined with each other as long as they do not conflict with each other. The embodiments described below with reference to the accompanying drawings are exemplary and are intended to explain the present disclosure, and should not be construed as limiting the present disclosure.

It should be noted that the term “a plurality of” mentioned in the description refers to two or more. The term “and/or” describes an association relationship of associated objects, indicating that there may be three relationships. For example, A and/or B may mean three situations: A exists alone, A and B exist at the same time, and B exists alone. The character “/” generally indicates that the associated objects before and after it have an “or” relationship.

Stretchable display technology enables a display screen to be stretchable and to be stretched in all directions to change its shape for adapting to surfaces of any shape. A stretchable screen may be flexibly applied in various fields, such as consumer electronics, public displays, medical, biological, wearable devices, gaming, fashion, and automotive scenarios. When the display screen is stretched, the tensile strength between a connecting wire and an isolation structure may directly affects the quality and life of the display screen. Therefore, how to enhance the tensile strength of the connecting wire and the isolation structure is a technical problem that needs to be solved urgently.

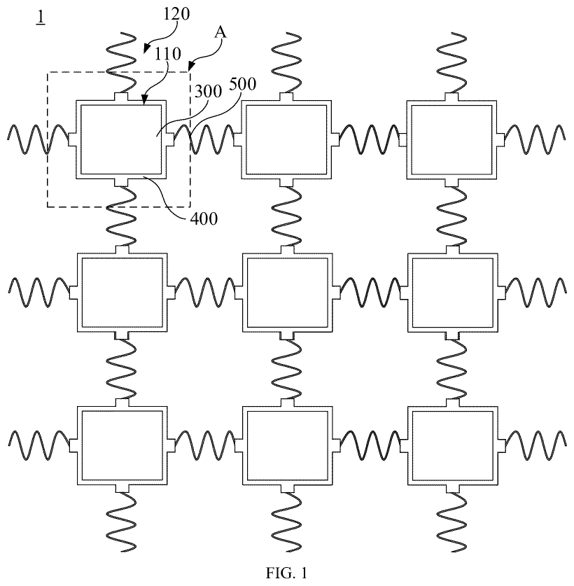

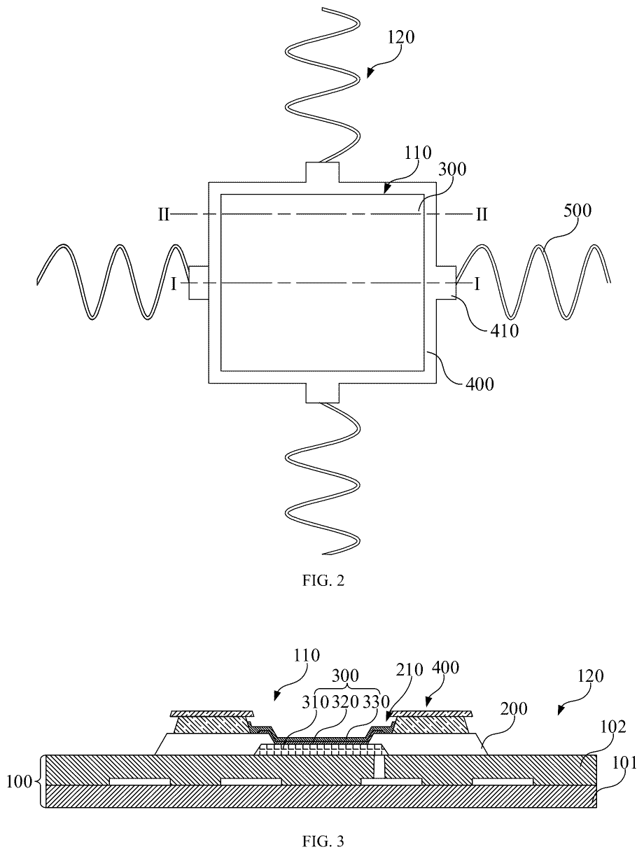

In order to solve the technical problems above, as shown in FIG. 1 to FIG. 5, a display panel 1 is provided in some embodiments of the present disclosure. The display panel 1 includes a flexible substrate 100, a plurality of pixel definition layers 200, a plurality of sub-pixels 300, a plurality of isolation structures 400, and a plurality of connecting wires 500. As shown in FIG. 1 and FIG. 2, the flexible substrate 100 is defined with a plurality of pixel regions 110 and a plurality of extension regions 120. As shown in FIG. 3, the pixel definition layers 200 are arranged within the pixel regions 110 respectively to form a plurality of pixel openings 210. The sub-pixels 300 are arranged in the pixel openings 210 respectively. Each of the sub-pixels 300 includes an anode 310, an organic light-emitting layer 320, and a cathode 330, which are sequentially stacked along a direction from close to the flexible substrate 100 to away from the flexible substrate 100. As shown in FIG. 4, the isolation structures 400 are arranged on the pixel definition layers 200 respectively. The isolation structures 400 surround the sub-pixels 300. A portion of each of the isolation structures 400 extends toward a side away from a corresponding one of the pixel openings 210 to form a reinforcement portion 410, and another portion of each of the isolation structures 400 connecting the reinforcement portion 410 is an isolation portion 420. Along a direction from the corresponding one of the pixel openings 210 to a corresponding one of the extension regions 120, a width of the reinforcement portion 410 is greater than a width of the isolation portion 420. As shown in FIG. 1, FIG. 2, and FIG. 4, the connecting wires 500 are arranged in the extension regions 120 respectively. Each of the connecting wires 500 is connected between two adjacent isolation structures 400 through reinforcement portions 410 of the two adjacent isolation structures 400. Along a width direction of each of the isolation structures 400, a width of a corresponding one of the connecting wires 500 is smaller than a width of the reinforcement portion 410. The width direction of each of the isolation structures 400 is an extension direction of the isolation portion 420 connected to the reinforcement portion 410.

As shown in FIG. 1 to FIG. 5, the pixel regions 110 defined on the flexible substrate 100 may be configured to accommodate the sub-pixels 300 respectively. The extension regions 120 may be configured to provide extension margins when the display screen is stretched, so that the display screen may be stretched in all directions. The pixel definition layers 200 are arranged in the pixel regions 110 respectively to form the pixel openings 210. The sub-pixels 300 are arranged in the pixel openings 210 respectively. The cathode 330 and the anode 310 of each sub-pixel 300 provide an electrical signal to the organic light-emitting layer 320 for enabling the organic light-emitting layer 320 to emit light through electroluminescence. The isolation structures 400 surround the sub-pixel 300 to isolate adjacent sub-pixels 300, so that adjacent sub-pixels 300 may be independently encapsulated. Two adjacent isolation structures 400 are connected by a corresponding connecting wire 500. The connecting wire 500 and the isolation structure 400 are interconnected through the reinforcement portion 410. Along the direction from the corresponding one of the pixel openings 210 to the corresponding one of the extension regions 120, the width of the reinforcement portion 410 is greater than the width of the isolation portion 420. Along the width direction of the isolation structure 400, the width of the connecting wire 500 is smaller than the width of the reinforcement portion 410. The connection strength between the connecting wire 500 and the isolation structure 400 is increased through the reinforcement portion 410, thereby increasing the tensile strength between the connecting wire 500 and the isolation structure 400.

In some embodiments, as shown in FIG. 1 and FIG. 2, the pixel regions 110 are arranged spaced apart, and the extension regions 120 are arranged spaced apart. In the same direction, the pixel regions 110 and the extension regions 120 are arranged alternately. When being stretched, the extension regions 120 arranged alternately may deform, and the extension regions 120 become longer in a stretching direction, while an area of the pixel regions 110 remains unchanged, thereby achieving the stretching of the display screen. The display screen may be stretched to a larger area through the multiple extension regions 120, thereby increasing the display area of the display screen.

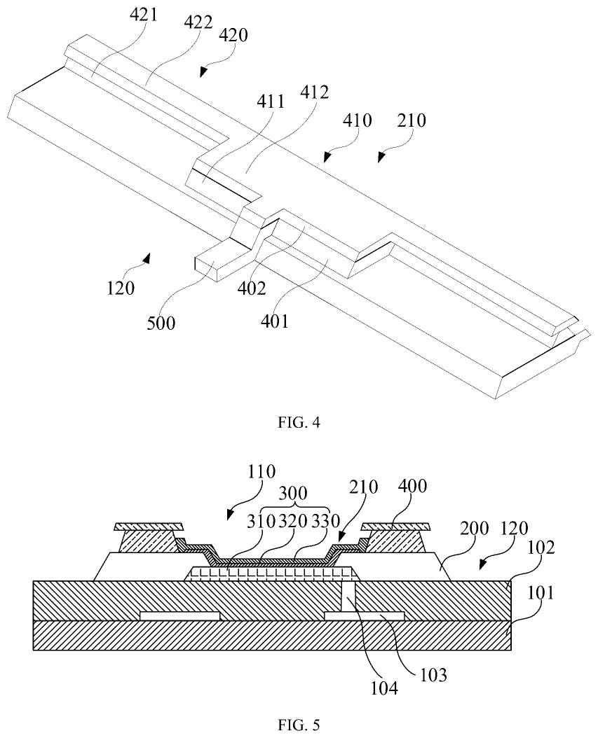

In some embodiments, as shown in FIG. 3 and FIG. 5, the flexible substrate 100 may be a glass flexible substrate or an organic flexible substrate. The organic flexible substrate includes a baseplate 101, a planarization layer 102, and a driving circuit 103. A material of the planarization layer 102 may be polyimide (PI) and polyethylene naphthalate (PEN). The driving circuit 103 may be a thin film transistor (TFT) circuit layer. The TFT circuit layer is configured to drive a light-emitting layer of an OLED. The TFT circuit layer includes a plurality of driving circuit units arranged in an array. Each driving circuit unit may include a TFT component and a capacitor. Each driving circuit unit corresponds to an anode 310 and an organic light-emitting layer 320. The TFT component is a low temperature poly-silicon (LTPS) type or a metal-oxide semiconductor (MOS) type, such as a metal-oxide semiconductor type of indium gallium zinc oxide (IGZO).

In some embodiments, as shown in FIG. 5, the flexible substrate 100 may further include a pad 104. The pad 104 is configured to connect the driving circuit 103 and the anode 310 to transmit an electrical signal.

In some embodiments, a material of the pixel definition layer 200 may be an organic material, with one of an organic material and an inorganic material arranged thereon as an inorganic coating layer. The organic material of the pixel definition layer 200 includes, but is not limited to, polyimide.

In some embodiments, the display panel 1 includes a plurality of pixels for emitting light of different colors. The pixels emit light to display an image. Each pixel is composed of sub-pixels 300 of three colors, namely red, green, and blue, which are superimposed and mixed to display a white image, and different color images are displayed by controlling the luminescence degree of the sub-pixels 300 of different colors.

In some embodiments, as shown in FIG. 3, the sub-pixel 300 includes the anode 310, the organic light-emitting layer 320, and the cathode 330. The anode 310 is arranged on the flexible substrate 100 within the pixel region 110. The organic light-emitting layer 320 is arranged on the anode 310. The cathode 330 is arranged on the organic light-emitting layer 320.

Further, as shown in FIG. 3, the anode 310 is arranged between the pixel definition layer 200 and the flexible substrate 100. The anode 310 is arranged spaced apart on a side surface of the flexible substrate 100. A material of the anode 310 includes, but is not limited to, chromium, titanium, gold, silver, copper, aluminum, indium tin oxide (ITO), combinations thereof, or other suitable conductive materials. The organic light-emitting layer 320 is configured to emit red light, blue light, or green light when powered on. The organic light-emitting layer 320 may include one or more of hole injection layer (HIL), hole transfer layer (HTL), emitting layer (EML), and electron transfer layer (ETL). The cathode 330 is arranged on a side of the organic light-emitting layer 320 away from the anode 310. A material of the cathode 330 includes, but is not limited to, chromium, titanium, gold, silver, copper, aluminum, ITO, combinations thereof, or other suitable conductive materials. The material of the cathode 330 may be the same as or different from the material of the anode 310, which may be arranged according to actual conditions.

In some embodiments, an initial pixel definition layer is formed on the anode 310 of the sub-pixel 300, and the initial pixel definition layer 200 is exposed and developed to form the pixel definition layer 200. In this way, the pixel definition layer 200 forms the pixel opening 210 located in the pixel region 110 above the anode 310 of each sub-pixel 300. The pixel definition layer 200 partially covers the anode 310 of the sub-pixel 300. An organic light-emitting material is evaporated on the pixel definition layer 200 and the anode 310 to form the organic light-emitting layer 320. A cathode material is evaporated on the organic light-emitting layer 320 to form the cathode 330.

In some embodiments, as shown in FIG. 1 and FIG. 2, the connecting wire 500 includes a plurality of crest segments and a plurality of trough segments. The crest segments and the trough segments are arranged in a staggered manner and interconnected to form a bridge-shaped routing line, which bends and extends in the extension region 120 and connects the adjacent isolation structures 400.

In some embodiments, as shown in FIG. 3 and FIG. 4, each of the isolation structures 400 includes a metal layer 401 and an insulating layer 402 arranged in sequence along the direction from close to the flexible substrate 100 to away from the flexible substrate 100. A portion of the metal layer 401 located at the reinforcement portion 410 is a first metal layer 411, and another portion of the metal layer 401 located at the isolation portion 420 is a second metal layer 421. A portion of the insulating layer 402 located at the reinforcement portion 410 is a first insulating layer 412, and another portion of the insulating layer 402 located at the isolation portion 420 is a second insulating layer 422. Along the direction from the corresponding one of the pixel openings 210 to the corresponding one of the extension regions 120, a width of the first metal layer 411 is greater than a width of the second metal layer 421, and a width of the first insulating layer 412 is greater than a width of the second insulating layer 422. In the present disclosure, the reinforcement portion 410 may play an isolation role. The reinforcement portion 410 is formed by increasing a thickness of the isolation structure 400 in a certain direction. When the reinforcement portion 410 is formed, the metal layer 401 and the insulating layer 402 need to be extended at the same time so that the insulating layer 402 may keep covering the metal layer 401, so as to improve the tensile strength by means of the first metal layer 411 and the first insulating layer 412. Since the isolation structures 400 are arranged around the pixel opening 210, the direction from the pixel opening 210 to the extension region 120 is a radial direction of the pixel opening 210.

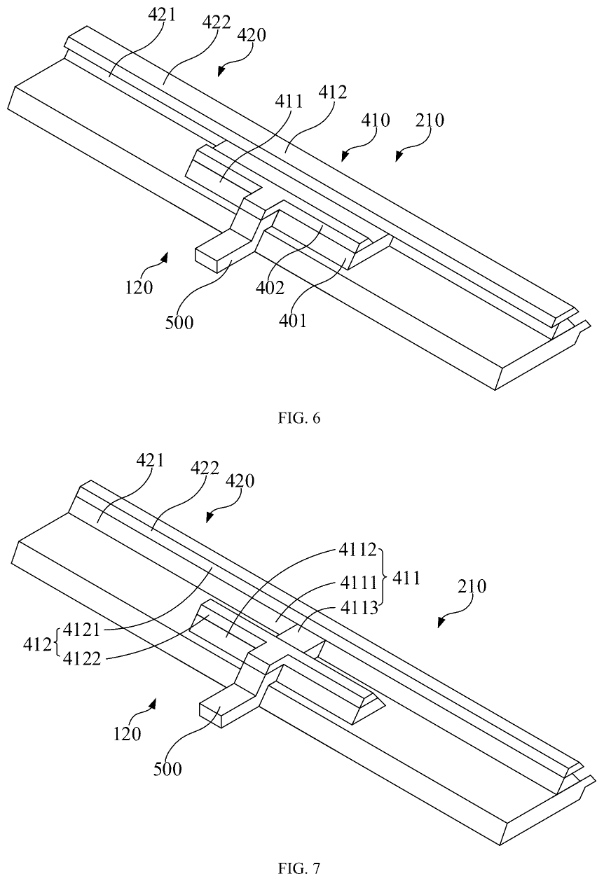

In some embodiments, as shown in FIG. 6, the first metal layer 411 is a continuous layer structure. The first metal layer 411 extends from the corresponding one of the pixel openings 210 to the corresponding one of the extension regions 120. Alternatively, as shown in FIG. 7, the first metal layer 411 is a fragmented layer structure. The first metal layer 411 includes a first sub-metal layer 4111, a second sub-metal layer 4112, and a connecting portion 4113. The first sub-metal layer 4111 and the second sub-metal layer 4112 are spaced apart from each other. The first sub-metal layer 4111 is close to the corresponding one of the pixel openings 210, the second sub-metal layer 4112 is close to the corresponding one of the extension regions 120, and the connecting portion 4113 is arranged between the first sub-metal layer 4111 and the second sub-metal layer 4112. The continuous layer structure is a continuous structure of the metal layer 401 or the insulating layer 402 on a surface. The fragmented layer structure is a structure in which the metal layer 401 or the insulating layer 402 is disconnected in an intermittent manner on a surface. In a case where the first metal layer 411 is a continuous layer structure, the process difficulty may be reduced and the process cost may be saved. In a case where the first metal layer 411 is a fragmented layer structure, the deformation capacity of the reinforcement portion 410 may be increased and the stress caused by deformation when bending may be released. In a case where the first metal layer 411 is a cross-section structure, along the width direction of the isolation structure 400, a width of the connecting portion 4113 is smaller than both a width of the first sub-metal layer 4111 and a width of the second sub-metal layer 4112, and the connecting portion 4113 is configured to play an electrical connection role between the first sub-metal layer 4111 and the second sub-metal layer 4112.

In some embodiments, as shown in FIG. 4, the first insulating layer 412 is a continuous layer structure. The first insulating layer 412 extends from the corresponding one of the pixel openings 210 to the corresponding one of the extension regions 120. A portion of the first insulating layer 412 extends to the corresponding one of the connecting wires 500. The first insulating layer 412 being a continuous layer structure may cover more areas of the first metal layer 411 and may reduce the process difficulty. As shown in FIG. 4, FIG. 6 and FIG. 7, the portion of the first insulating layer 412 extending to the connecting wire 500 may overlap with a portion of the connecting wire 500. The first insulating layer 412 extends at least beyond a connection between the first metal layer 411 and the connecting wire 500, so as to protect the portion of the connecting wire 500. The first insulating layer 412 is a continuous layer structure and may be combined with the first metal layer 411 which is also a continuous layer structure to form a type of reinforcement portion 410 of the isolation structure 400. The first insulating layer 412 is a continuous layer structure and may be combined with the first metal layer 411 which is a fragmented layer structure to form another type of reinforcement portion 410 of the isolation structure 400.

In some embodiments, as shown in FIG. 6 and FIG. 7, the first insulating layer 412 is a fragmented layer structure. The first insulating layer 412 includes a first sub-insulating layer 4121 and a second sub-insulating layer 4122 that are spaced apart. The first sub-insulating layer 4121 is close to the corresponding one of the pixel openings 210, and the second sub-insulating layer 4122 is close to the corresponding one of the extension regions 120. The first sub-insulating layer 4121 is arranged on the first metal layer 411 and extends outside of the first metal layer 411 along a direction from the corresponding one of the extension regions 120 to the corresponding one of the pixel openings 210. The second sub-insulating layer 4122 is arranged on the first metal layer 411. A portion of the second sub-insulating layer 4122 extends outside of the first metal layer 411 along the direction from the corresponding one of the pixel openings 210 to the corresponding one of the extension regions 120. Another portion of the second sub-insulating layer 4122 overlaps with a portion of the corresponding one of the connecting wires 500. The first insulating layer 412 being a fragmented layer structure may increase the deformation capacity of the reinforcement portion 410 and release the stress caused by the deformation more easily when bending. The first insulating layer 412 is a fragmented layer structure and may be combined with the first metal layer 411 which is a fragmented layer structure to form a type of reinforcement portion 410 of the isolation structure 400. The second insulating layer 422 is a fragmented layer structure and may be combined with the first metal layer 411 which is a continuous layer structure to form another type of reinforcement portion 410 of the isolation structure 400.

In some embodiments, as shown in FIG. 8, the first insulating layer 412 is a continuous layer structure. The first insulating layer 412 extends from the corresponding one of the pixel openings 210 to the corresponding one of the extension regions 120. The first insulating layer 412 extends to a side of the first metal layer 411 away from the corresponding one of the pixel openings 210. The first insulating layer 412 does not cover the connecting wire 500 but exposes the connecting wire 500 outside the insulating layer 402, and the connecting wire 500 may be sealed through subsequent encapsulation. In this way, the deformation ability of the connecting wire 500 may be enhanced, enabling the connecting wire 500 to release the stress caused by deformation more easily when bending.

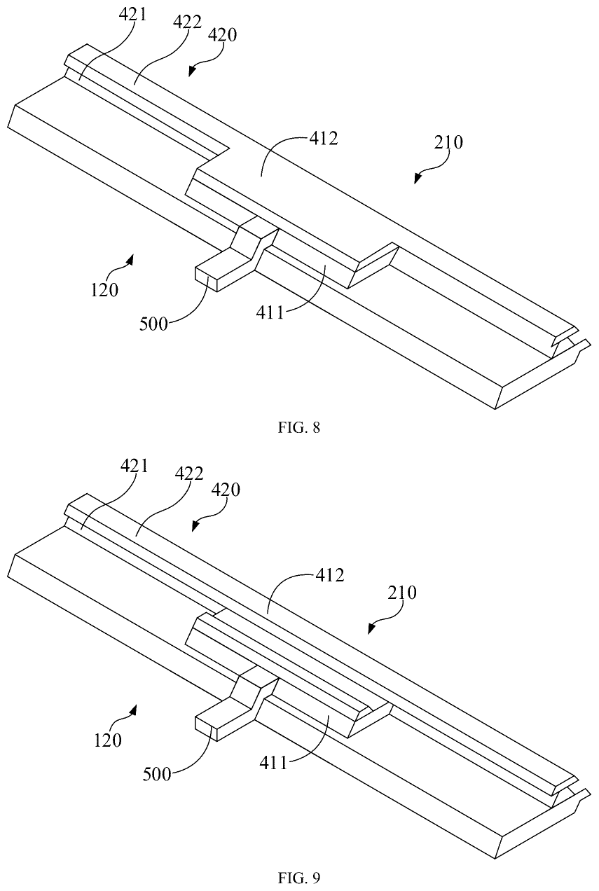

In some embodiments, as shown in FIG. 9, the first insulating layer 412 is a fragmented layer structure. The first insulating layer 412 includes a first sub-insulating layer 4121 and a second sub-insulating layer 4122 that are spaced apart. The first sub-insulating layer 4121 is close to the corresponding one of the pixel openings 210, and the second sub-insulating layer 4122 is close to the corresponding one of the extension regions 120. The first sub-insulating layer 4121 is arranged on the first metal layer 411 and extends outside of the first metal layer 411 along a direction from the corresponding one of the extension regions 120 to the corresponding one of the pixel openings 210. The second sub-insulating layer 4122 is arranged on the first metal layer 411. The second sub-insulating layer 4122 extends to a side of the first metal layer 411 away from the corresponding one of the pixel openings 210 along the direction from the corresponding one of the pixel openings 210 to the corresponding one of the extension regions 120. That is, the first sub-insulating layer 4121 may shield the first metal layer 411 on a side of the pixel opening 210 during evaporation. The second sub-insulating layer 4122 is flush with a side surface of the first metal layer 411 away from the pixel opening 210, and does not cover the connecting wire 500, thereby further enabling the connecting wire 500 to release the stress caused by deformation more effectively when bending.

In some embodiments, the first insulating layer 412 extends to the outside of the first metal layer 411 along a side towards the pixel opening 210. That is, a side of the first insulating layer 412 facing the pixel opening 210 may extend beyond the first metal layer 411, so as to achieve different evaporation angles for different sub-pixels 300, thereby enabling the display panel 1 to emit light.

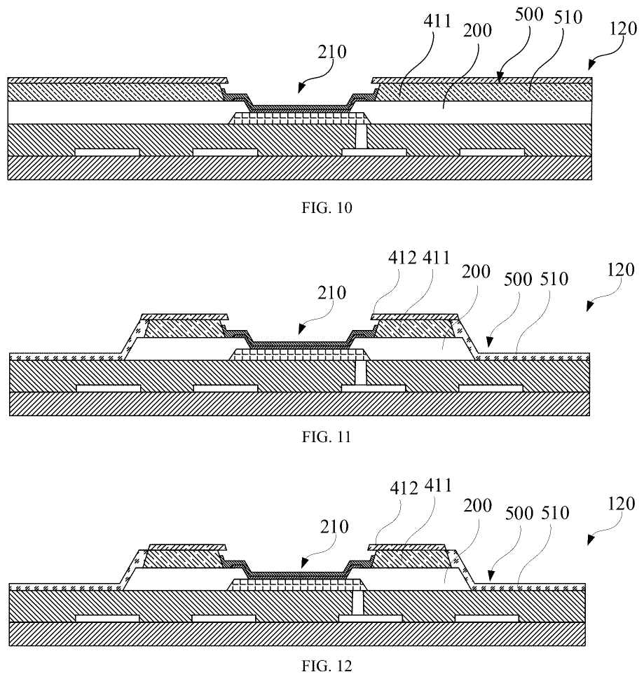

In some embodiments, as shown in FIG. 10, the pixel definition layer 200 extends from one of the pixel openings 210 to another one of the pixel openings 210 through a corresponding one of the extension regions 120. Each of the connecting wires 500 includes a third metal layer 510. The third metal layer 510 is arranged between two adjacent first metal layers 411. The third metal layer 510 is arranged on a corresponding one of the pixel definition layers 200. The pixel definition layer 200 extends from one pixel opening 210 to another pixel opening 210 to be arranged within the extension region 120. In this way, the structural strength of the extension region 120 may be increased and the manufacturing of the extension region 120 may be more facilitated. The third metal layer 510 extends along the pixel definition layer 200 and is connected between two adjacent first metal layers 411.

In some embodiments, as shown in FIG. 11 and FIG. 12, each of the pixel definition layers 200 extends from a corresponding one of the pixel openings 210 to a corresponding one of the extension regions 120. The pixel definition layers 200 corresponding to two adjacent pixel regions 110 are arranged spaced apart from each other. Each of the connecting wires 500 includes a third metal layer 510. The third metal layer 510 is arranged between two adjacent first metal layers 411, and the third metal layer 510 extends from one of the pixel definition layers 200 to another one of the pixel definition layers 200 through the flexible substrate 100 within a corresponding one of the extension regions 120. The pixel definition layers 200 corresponding to two adjacent pixel regions 110 are arranged spaced apart to form the extension region 120, that is, the flexible substrate 100, the connecting wires 500, and other structures are arranged within the extension region 120, but the pixel definition layers 200 are not arranged within the extension region 120. During a deposition process, a portion of the first metal layer 411 is transformed to form the connecting wire 500 along a surface of the pixel definition layer 200 and a surface of the flexible substrate 100. That is, the connecting wire 500 extends in a bent manner within the extension region 120. In this way, the stress of the connecting wire 500 caused by deformation may be further released when bending. As shown in FIG. 11, the first insulating layer 412 extends beyond the first metal layer 411 along the direction from the pixel opening 210 to the extension region 120. As shown in FIG. 12, the first insulating layer 412 extends to the side of the first metal layer 411 along the direction from the pixel opening 210 to the extension region 120, and is flush with the side surface of the first metal layer 411.

In some embodiments, the width of the first insulating layer 412 gradually decreases from a side close to the flexible substrate 100 to another side away from the flexible substrate 100, and the width of the first metal layer 411 gradually decreases from a side close to the flexible substrate 100 to another side away from the flexible substrate 100. The width of the first metal layer 411 gradually decreases from the side close to the flexible substrate 100 to the another side away from the flexible substrate 100. A width of the first metal layer 411 close to the first insulating layer 412 is smaller than a width of the first insulating layer 412 close to the first metal layer 411. In this way, the isolation structure 400 may be formed in a “mushroom” shape, which may play a shielding role when evaporating the organic light-emitting layer 320 and the cathode 330 of the sub-pixel 300, and organic light-emitting layers 320 and cathodes 330 of adjacent sub-pixels 300 may be isolated from the reinforcement portion 410 by means of different shielding angles.

In some embodiments, a cross-section of the reinforcement portion 410 may be circular, trapezoidal, or polygonal, depending on actual conditions.

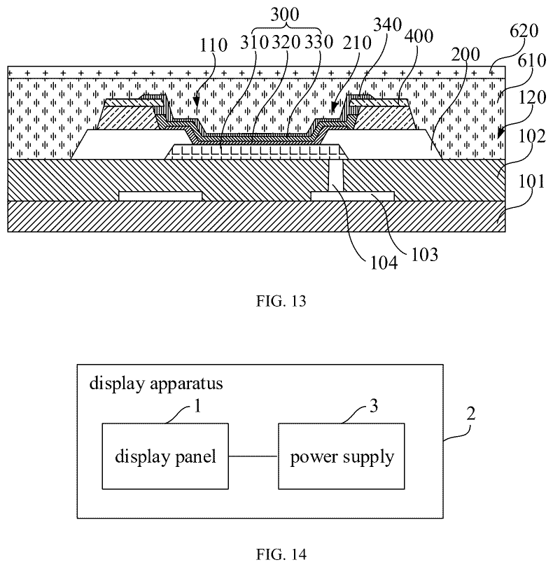

In some embodiments, as shown in FIG. 13, the sub-pixel 300 further includes an insulating protective layer 340. The insulating protective layer 340 is arranged on the cathode 330. The insulating protective layer 340 extends along both sides of the cathode 330 to the first metal layers 411 of the isolation structures 400. The insulating protective layer 340 is configured to provide insulation protection for the cathode 330 and the isolation structures 400. The insulating protective layer 340 may be an inorganic material.

In some embodiments, as shown in FIG. 13, the display panel 1 further includes a first encapsulation layer 610 and a second encapsulation layer 620. The first encapsulation layer 610 is encapsulated on the extension regions 120 and the pixel regions 110, and the second encapsulation layer 620 is encapsulated on the first encapsulation layer 610, thereby forming a multi-layer encapsulation for the display panel 1. In this way, the display panel 1 has better wear resistance and the service life of the display panel 1 may be effectively increased.

As shown in FIG. 14, the present disclosure also provides a display device 2, including the display panel 1 mentioned above and a power supply 3. The power supply 3 is electrically connected to the display panel 1 for supplying power to the display panel 1. The tensile strength of the display screen may be improved by the display panel 1 mentioned above, so that the display device 2 has a better display effect.

In the present disclosure, unless otherwise clearly specified and limited, the terms “arranged (defined)”, “connected” and the like should be understood in a broad sense. For example, it may be a fixed connection, a detachable connection, or an integral connection; it may be a mechanical connection or an electrical connection; it may be a direct connection or an indirect connection through an intermediate medium, it may be an internal communication of two elements or an interaction relationship between two elements. For those of ordinary skill in the art, the specific meanings of the above terms in the present disclosure may be understood according to specific circumstances.

In the specification of the present disclosure, the description with reference to terms such as “some embodiments” means that the specific features, structures, materials, or characteristics described in conjunction with the embodiments are included in at least one embodiment of the present disclosure. In the specification, the schematic representation of the above terms does not necessarily refer to the same embodiment or example. Moreover, the specific features, structures, materials, or characteristics described may be combined in a suitable manner in any one or more embodiments or examples. In addition, without mutual contradiction, those skilled in the art can combine and integrate different embodiments or examples described in the specification, as well as the features of different embodiments or examples.

Although the embodiments of the present disclosure have been shown and described above, it can be understood that the above embodiments are exemplary and should not be construed as limiting the present disclosure. Those of ordinary skill in the art can make changes, modifications, substitutions, and modifications to the above embodiments within the scope of the present disclosure. Therefore, any changes or modifications made in accordance with the claims and description of the present disclosure should fall within the scope of the patent of the present disclosure.

1. A display panel, comprising:
a flexible substrate, defined with a plurality of pixel regions and a plurality of extension regions;
a plurality of pixel definition layers, arranged within the pixel regions respectively to form a plurality of pixel openings;
a plurality of sub-pixels, arranged in the pixel openings respectively, wherein each of the sub-pixels comprises an anode, an organic light-emitting layer, and a cathode, which are sequentially stacked along a direction from close to the flexible substrate to away from the flexible substrate;
a plurality of isolation structures, arranged on the pixel definition layers respectively and surrounding the sub-pixels, wherein a portion of each of the isolation structures extends toward a side away from a corresponding one of the pixel openings to form a reinforcement portion, another portion of each of the isolation structures connecting the reinforcement portion is an isolation portion; and along a direction from the corresponding one of the pixel openings to a corresponding one of the extension regions, a width of the reinforcement portion is greater than a width of the isolation portion;
a plurality of connecting wires, arranged in the extension regions respectively, wherein each of the connecting wires is connected between two adjacent isolation structures through reinforcement portions of the two adjacent isolation structures; and along a width direction of each of the isolation structures, a width of a corresponding one of the connecting wires is smaller than a width of the reinforcement portion.

2. The display panel according to claim 1, wherein each of the isolation structures comprises a metal layer and an insulating layer arranged in sequence along the direction from close to the flexible substrate to away from the flexible substrate;
a portion of the metal layer located at the reinforcement portion is a first metal layer, and another portion of the metal layer located at the isolation portion is a second metal layer;
a portion of the insulating layer located at the reinforcement portion is a first insulating layer, and another portion of the insulating layer located at the isolation portion is a second insulating layer;
along the direction from the corresponding one of the pixel openings to the corresponding one of the extension regions, a width of the first metal layer is greater than a width of the second metal layer, and a width of the first insulating layer is greater than a width of the second insulating layer.

3. The display panel according to claim 2, wherein the first metal layer is a continuous layer structure, and the first metal layer extends from the corresponding one of the pixel openings to the corresponding one of the extension regions.

4. The display panel according to claim 2, wherein the first metal layer is a fragmented layer structure, and the first metal layer comprises a first sub-metal layer, a second sub-metal layer, and a connecting portion, and the first sub-metal layer and the second sub-metal layer are spaced apart from each other; the first sub-metal layer is close to the corresponding one of the pixel openings, the second sub-metal layer is close to the corresponding one of the extension regions, and the connecting portion is arranged between the first sub-metal layer and the second sub-metal layer.

5. The display panel according to claim 2, wherein the first insulating layer is a continuous layer structure, the first insulating layer extends from the corresponding one of the pixel openings to the corresponding one of the extension regions, and a portion of the first insulating layer extends to the corresponding one of the connecting wires.

6. The display panel according to claim 2, wherein the first insulating layer is a fragmented layer structure, and the first insulating layer includes a first sub-insulating layer and a second sub-insulating layer that are spaced apart; the first sub-insulating layer is close to the corresponding one of the pixel openings, and the second sub-insulating layer is close to the corresponding one of the extension regions; the first sub-insulating layer is arranged on the first metal layer and extends outside of the first metal layer along a direction from the corresponding one of the extension regions to the corresponding one of the pixel openings; the second sub-insulating layer is arranged on the first metal layer, a portion of the second sub-insulating layer extends outside of the first metal layer along the direction from the corresponding one of the pixel openings to the corresponding one of the extension regions, and another portion of the second sub-insulating layer overlaps with a portion of the corresponding one of the connecting wires.

7. The display panel according to claim 2, wherein the first insulating layer is a continuous layer structure, the first insulating layer extends from the corresponding one of the pixel openings to the corresponding one of the extension regions, and the first insulating layer extends to a side of the first metal layer away from the corresponding one of the pixel openings.

8. The display panel according to claim 2, wherein the first insulating layer is a fragmented layer structure, and the first insulating layer includes a first sub-insulating layer and a second sub-insulating layer that are spaced apart; the first sub-insulating layer is close to the corresponding one of the pixel openings, and the second sub-insulating layer is close to the corresponding one of the extension regions; the first sub-insulating layer is arranged on the first metal layer and extends outside of the first metal layer along a direction from the corresponding one of the extension regions to the corresponding one of the pixel openings; the second sub-insulating layer is arranged on the first metal layer, and the second sub-insulating layer extends to a side of the first metal layer away from the corresponding one of the pixel openings along the direction from the corresponding one of the pixel openings to the corresponding one of the extension regions.

9. The display panel according to claim 2, wherein each of the pixel definition layers extends from one of the pixel openings to another one of the pixel openings through a corresponding one of the extension regions; each of the connecting wires comprises a third metal layer, the third metal layer is arranged between two adjacent first metal layers, and the third metal layer is arranged on a corresponding one of the pixel definition layers.

10. The display panel according to claim 2, wherein each of the pixel definition layers extends from a corresponding one of the pixel openings to a corresponding one of the extension regions, and the pixel definition layers corresponding to two adjacent pixel regions are arranged spaced apart from each other;
each of the connecting wires comprises a third metal layer, the third metal layer is arranged between two adjacent first metal layers, and the third metal layer extends from one of the pixel definition layers to another one of the pixel definition layers through the flexible substrate within a corresponding one of the extension regions.

11. The display panel according to claim 2, wherein the width of the first insulating layer gradually decreases from a side close to the flexible substrate to another side away from the flexible substrate, and the width of the first metal layer gradually decreases from a side close to the flexible substrate to another side away from the flexible substrate.

12. The display panel according to claim 2, wherein along the direction from the corresponding one of the pixel openings to the corresponding one of the extension regions, a width of the first metal layer close to the first insulating layer is smaller than a width of the first insulating layer close to the first metal layer.

13. The display panel according to claim 2, wherein the first insulating layer extends to an outside of the first metal layer along a side towards the pixel opening.

14. The display panel according to claim 1, wherein the pixel regions are arranged spaced apart, and the extension regions are arranged spaced apart; and in the same direction, the pixel regions and the extension regions are arranged alternately.

15. A display apparatus, comprising:
a display panel, comprising:
a flexible substrate, defined with a plurality of pixel regions and a plurality of extension regions;
a plurality of pixel definition layers, arranged within the pixel regions respectively to form a plurality of pixel openings;
a plurality of sub-pixels, arranged in the pixel openings respectively, wherein each of the sub-pixels comprises an anode, an organic light-emitting layer, and a cathode, which are sequentially stacked along a direction from close to the flexible substrate to away from the flexible substrate;
a plurality of isolation structures, arranged on the pixel definition layers respectively and surrounding the sub-pixels, wherein a portion of each of the isolation structures extends toward a side away from a corresponding one of the pixel openings to form a reinforcement portion, another portion of each of the isolation structures connecting the reinforcement portion is an isolation portion; and along a direction from the corresponding one of the pixel openings to a corresponding one of the extension regions, a width of the reinforcement portion is greater than a width of the isolation portion;
a plurality of connecting wires, arranged in the extension regions respectively, wherein each of the connecting wires is connected between two adjacent isolation structures through reinforcement portions of the two adjacent isolation structures; and along a width direction of each of the isolation structures, a width of a corresponding one of the connecting wires is smaller than a width of the reinforcement portion;
a power supply, electrically connected to the display panel for supplying power to the display panel.

16. The display apparatus according to claim 15, wherein each of the isolation structures comprises a metal layer and an insulating layer arranged in sequence along the direction from close to the flexible substrate to away from the flexible substrate;
a portion of the metal layer located at the reinforcement portion is a first metal layer, and another portion of the metal layer located at the isolation portion is a second metal layer;
a portion of the insulating layer located at the reinforcement portion is a first insulating layer, and another portion of the insulating layer located at the isolation portion is a second insulating layer;
along the direction from the corresponding one of the pixel openings to the corresponding one of the extension regions, a width of the first metal layer is greater than a width of the second metal layer, and a width of the first insulating layer is greater than a width of the second insulating layer.

17. The display apparatus according to claim 16, wherein the first metal layer is a continuous layer structure, and the first metal layer extends from the corresponding one of the pixel openings to the corresponding one of the extension regions; or
the first metal layer is a fragmented layer structure, and the first metal layer comprises a first sub-metal layer, a second sub-metal layer, and a connecting portion, and the first sub-metal layer and the second sub-metal layer are spaced apart from each other; the first sub-metal layer is close to the corresponding one of the pixel openings, the second sub-metal layer is close to the corresponding one of the extension regions, and the connecting portion is arranged between the first sub-metal layer and the second sub-metal layer.

18. The display apparatus according to claim 16, wherein the first insulating layer is a continuous layer structure, the first insulating layer extends from the corresponding one of the pixel openings to the corresponding one of the extension regions, and a portion of the first insulating layer extends to the corresponding one of the connecting wires; or
the first insulating layer is a fragmented layer structure, and the first insulating layer includes a first sub-insulating layer and a second sub-insulating layer that are spaced apart; the first sub-insulating layer is close to the corresponding one of the pixel openings, and the second sub-insulating layer is close to the corresponding one of the extension regions; the first sub-insulating layer is arranged on the first metal layer and extends outside of the first metal layer along a direction from the corresponding one of the extension regions to the corresponding one of the pixel openings; the second sub-insulating layer is arranged on the first metal layer, a portion of the second sub-insulating layer extends outside of the first metal layer along the direction from the corresponding one of the pixel openings to the corresponding one of the extension regions, and another portion of the second sub-insulating layer overlaps with a portion of the corresponding one of the connecting wires.

19. The display apparatus according to claim 16, wherein the first insulating layer is a continuous layer structure, the first insulating layer extends from the corresponding one of the pixel openings to the corresponding one of the extension regions, and the first insulating layer extends to a side of the first metal layer away from the corresponding one of the pixel openings; or
the first insulating layer is a fragmented layer structure, and the first insulating layer includes a first sub-insulating layer and a second sub-insulating layer that are spaced apart; the first sub-insulating layer is close to the corresponding one of the pixel openings, and the second sub-insulating layer is close to the corresponding one of the extension regions; the first sub-insulating layer is arranged on the first metal layer and extends outside of the first metal layer along a direction from the corresponding one of the extension regions to the corresponding one of the pixel openings; the second sub-insulating layer is arranged on the first metal layer, and the second sub-insulating layer extends to a side of the first metal layer away from the corresponding one of the pixel openings along the direction from the corresponding one of the pixel openings to the corresponding one of the extension regions.

20. The display apparatus according to claim 15, wherein the pixel regions are arranged spaced apart, and the extension regions are arranged spaced apart; and in the same direction, the pixel regions and the extension regions are arranged alternately.
